(19) United States
(12) Patent Application Publication
(10) Pub. No.: US 2025/0187831 A1
(43) Pub. Date: Jun. 12, 2025

(54) Transport Facility

(71) Applicant: Daifuku Co., Ltd., Osaka-shi (JP)

(72) Inventors: Daisuke Ogawa, Hinocho (JP); Hiroshi Otsuka, Hinocho (JP); Tadashi Nishikawa, Hinocho (JP); Kenshin Hashiguchi, Hinocho (JP); Yuya Hirao, Hinocho (JP); Daichi Tomida, Hinocho (JP); Kosuke Kimura, Hinocho (JP)

(21) Appl. No.: 18/976,664

(22) Filed: Dec. 11, 2024

(30) Foreign Application Priority Data
Dec. 12, 2023 (JP) 2023-209525

(51) Int. Cl. B65G 1/06; B65G 1/04

(52) U.S. Cl. CPC B65G 1/065; B65G 1/0457

(57) ABSTRACT

A transport facility includes a transport vehicle that transports a transport article along a movement path, a wireless communicator that performs wireless communication with the transport vehicle, and a movable object movable separately from the transport vehicle. The movable object includes an information collector that collects communication state information indicating a state of wireless communication between the transport vehicle and the wireless communicator.

### CROSS-REFERENCE TO RELATED APPLICATION

This application claims priority to Japanese Patent Application No. 2023-209525 filed Dec. 12, 2023, the disclosure of which is hereby incorporated by reference in its entirety.

### BACKGROUND OF THE INVENTION

### Field of the Invention

The present invention relates to a transport facility including a transport vehicle that transports a transport article and a wireless communicator that performs wireless communication with the transport vehicle.

### Description of Related Art

Japanese Unexamined Patent Application Publication No. 2011-166671 (hereafter referred to as JP 2011-166671) describes a transport facility including a transport vehicle (12) that transports a transport article and a wireless communicator (8) that performs wireless communication with the transport vehicle (12). Reference signs in parentheses used in describing the background are the reference signs in JP 2011-166671.

### SUMMARY OF THE INVENTION

Wireless communication is typically more susceptible to the surrounding environment such as obstacles and radio interference than wired communication. To improve the wireless communication environment, the state of the wireless communication between a transport vehicle and a wireless communicator may be monitored. Monitoring the wireless communication state between the transport vehicle and the wireless communicator allows an appropriate wireless communication environment to be maintained through, for example, a restart, changes in the installation position, or replacement of the wireless communicator. The degree by which wireless communication is affected or whether wireless communication is affected by the surrounding environment can vary based on changes in the layout or the system configuration of the transport facility. The state of communication between the transport vehicle and the wireless communicator may thus be monitored both at the time of installation of the transport facility and subsequently. Thus, the state of wireless communication between the transport vehicle and the wireless communicator is to be monitored easily.

One or more aspects are directed to a transport facility in which the state of the wireless communication between the transport vehicle and the wireless communicator can be monitored easily.

In response to the above, a transport facility includes at least one transport vehicle that transports a transport article along a movement path, a wireless communicator that performs wireless communication with the at least one transport vehicle, and a movable object movable separately from the at least one transport vehicle. The movable object includes an information collector that collects communication state information indicating a state of wireless communication between the at least one transport vehicle and the wireless communicator.

In this structure, the communication state information indicating the state of the wireless communication between the transport vehicle and the wireless communicator can be collected by the movable object moving separately from the transport vehicle. The state of the wireless communication between the transport vehicle and the wireless communicator can thus be monitored easily based on the communication state information. This allows, for example, determination as to whether the wireless communication environment between the transport vehicle and the wireless communicator is appropriate and improves the wireless communication environment.

In this structure, the movable object moves separately from the transport vehicle, and can collect the communication state information without affecting transportation of a transport article performed by the transport vehicle.

### BRIEF DESCRIPTION OF THE DRAWINGS

FIG. 1 is a plan view of a transport facility according to an embodiment.

FIG. 2 is a perspective view of a transport vehicle included in the transport facility according to the embodiment.

FIG. 3 is a block diagram of the transport facility according to the embodiment.

FIG. 4 is a diagram describing collection of communication state information performed by an information collector during a load applying process.

FIG. 5 is a diagram of a movable object collecting the communication state information with the information collector.

### DESCRIPTION OF THE INVENTION

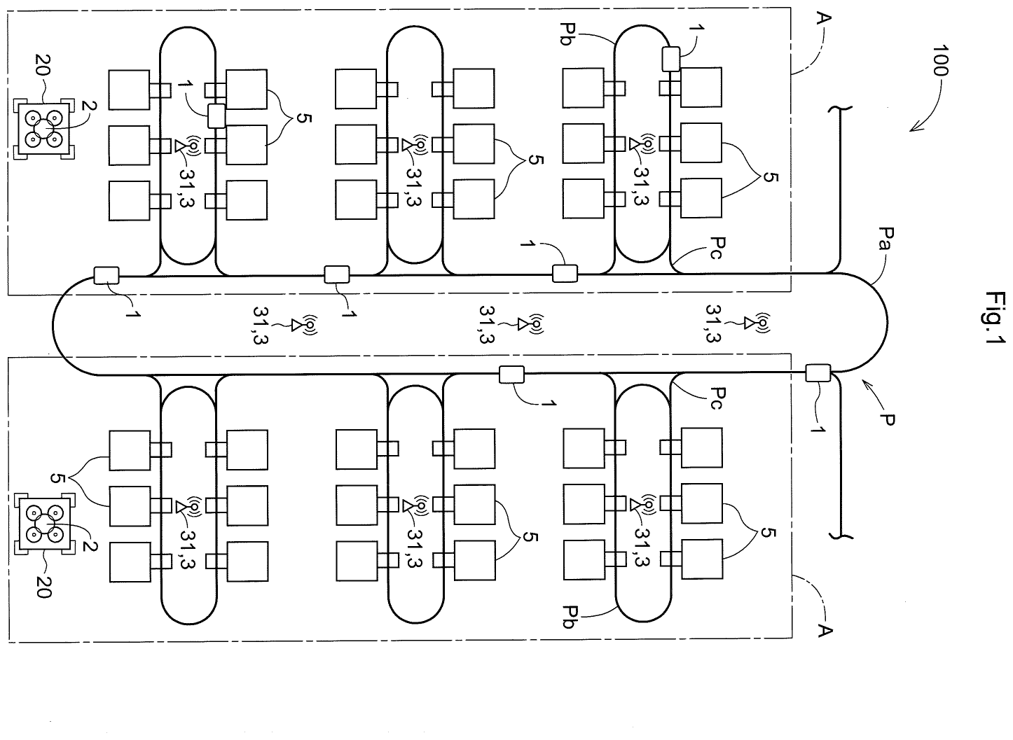

A transport facility 100 according to an embodiment will be described below with reference to the drawings. As shown in FIG. 1, the transport facility 100 includes at least one transport vehicle 1, at least one movable object 2, and a wireless communicator 3. In the present embodiment, the transport facility 100 includes multiple transport vehicles 1 and multiple movable objects 2.

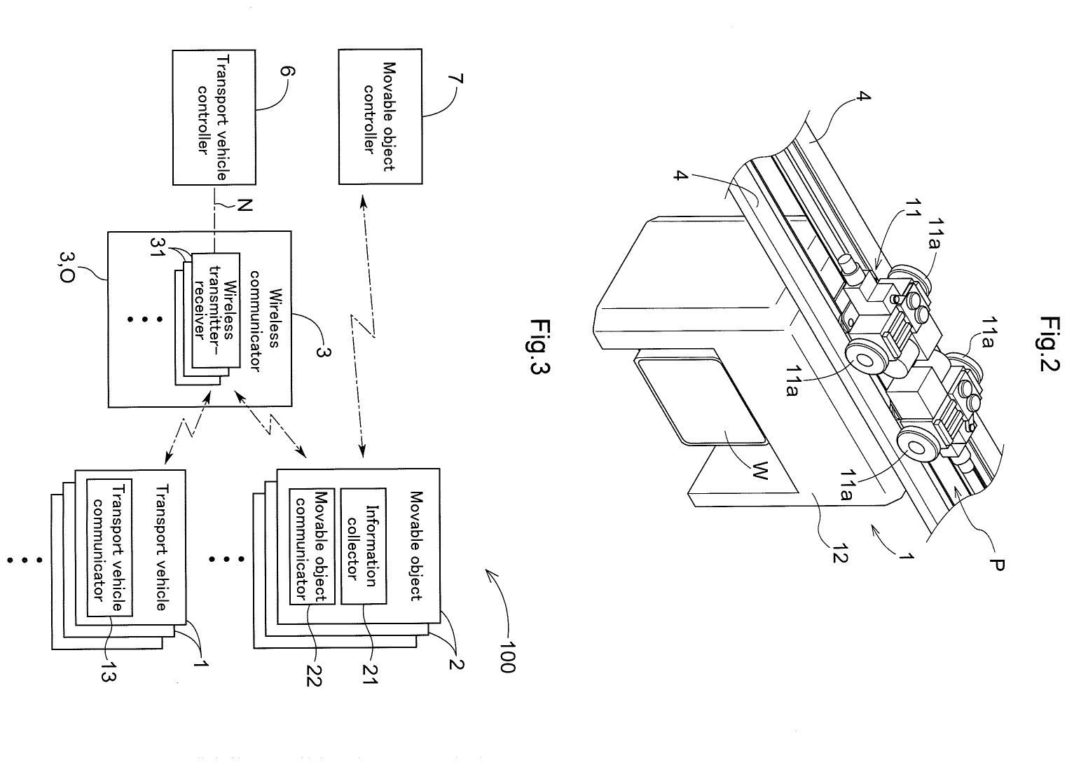

Each transport vehicle 1 transports a transport article W (refer to FIG. 2) along a movement path P. The transport article W is, for example, a front opening unified pod (FOUP) containing semiconductor wafers.

The movable objects 2 move separately from the transport vehicles 1. In the present embodiment, each movable object 2 is movable on a path different from the movement path P. In the present example, each movable object 2 is an unmanned aerial vehicle that flies within a preset flight area A. In the present example, the transport facility 100 includes at least one flight area A to allow at least one movable object 2 to correspond to one flight area A. In the present example, the transport facility 100 includes standby units 20 at which the movable objects 2 as unmanned aerial vehicles depart, land, or are on standby after landing. The standby units 20 may include chargers for charging the batteries in the movable objects 2.

As shown in FIG. 2, the transport facility 100 in the present embodiment further includes rails 4 extending along the movement path P. The transport vehicles 1 travel on the rails 4. In the example shown in FIG. 2, the rails 4 as a pair are horizontally spaced from each other and hung from the ceiling. In other words, in the present example, the transport vehicles 1 are ceiling-hung transport vehicles.

In the present embodiment, each transport vehicle 1 includes a traveler 11 that travels along the movement path P and a body 12 connected to the traveler 11.

The traveler 11 includes travel wheels 11a that roll on the travel surfaces (upper surfaces in this example) of the rails 4. The travel wheels 11a are rotated by a travel driver (not shown), or for example, by an electric motor such as a servomotor.

The body 12 is disposed below the rails 4 and hung from the traveler 11. The body 12 includes a support and a lift (not shown). The support is supported on the traveler 11 to be lifted and lowered with respect to the traveler 11 and suspends the transport article W. The lift lifts and lowers the support.

In the example shown in FIG. 2, the transport vehicle 1 is a ceiling-hung transport vehicle that travels along the rails 4 hung from the ceiling. However, the transport vehicle 1 may be of any other type. For example, the transport vehicle 1 may be a tracked transport vehicle that travels along rails on a floor surface. The transport vehicle 1 may also be a trackless transport vehicle such as an automated guided vehicle (AGV) or an autonomous mobile robot (AMR). The transport vehicle 1 being a trackless transport vehicle travels along a virtual movement path P, instead of a physical movement path P that includes rails or other members. In this case, the movement path P is virtually defined to connect multiple detectable members such as two-dimensional codes or radio frequency (RF) tags installed on the floor surface. The movement path P may also be virtually defined based on a route calculated using recognition results of the surrounding environment, without such detectable members on the floor surface.

As shown in FIG. 1, the movement path P in the present embodiment includes a looped primary path Pa, multiple looped secondary paths Pb each extending through multiple processing devices 5, and multiple connecting paths Pc connecting the primary path Pa and the secondary paths Pb.

Each processing device 5 performs predetermined processing on the transport article W (or an object contained in the transport article W). For example, the transport vehicle 1 loads the transport article W to be processed in the processing device 5 into the processing device 5 and unloads the transport article W processed in the processing device 5 from the processing device 5.

As shown in FIG. 3, the wireless communicator 3 performs wireless communication with the transport vehicles 1. In the present embodiment, the wireless communicator 3 includes multiple wireless transmitter-receivers 31 arranged in a distributed manner (refer also to FIG. 1). Each wireless transmitter-receiver 31 functions as an access point in wireless communication. In the present embodiment, the wireless transmitter-receivers 31 are installed at multiple positions along the movement path P in the transport facility 100. In the present application, wireless communication refers to communication performed under a predetermined wireless communication standard, such as Wi-Fi (registered trademark), Bluetooth (registered trademark), or ZigBee (registered trademark).

In the present embodiment, each transport vehicle 1 further includes a transport vehicle communicator 13 that performs wireless communication with the wireless communicator 3.

The transport vehicle communicator 13 functions as a wireless station that performs wireless communication with the wireless transmitter-receivers 31. The transport vehicle communicator 13 establishes a communication link with a destination transmitter-receiver 31C (e.g., the wireless transmitter-receiver 31 having the highest radio field intensity) selected from the multiple wireless transmitter-receivers 31. The transport vehicle communicator 13 is then connected to and communicates with the destination transmitter-receiver 31C. While traveling, the transport vehicle 1 switches the destination transmitter-receiver 31C with which the transport vehicle communicator 13 in the transport vehicle 1 establishes a communication link (performs roaming). For example, in response to the radio field intensity received from the connected destination transmitter-receiver 31C being lower than or equal to a predetermined value, the destination transmitter-receiver 31C is switched.

As described above, each of the multiple transport vehicles 1 in the present embodiment is connected to and communicates with the destination transmitter-receiver 31C selected from the multiple wireless transmitter-receivers 31 and moves along the movement path P while switching the destination transmitter-receiver 31C.

Each movable object 2 includes an information collector 21. The information collector 21 collects communication state information i. The communication state information i indicates the state of the wireless communication between the transport vehicles 1 and the wireless communicator 3 (e.g., the radio field intensity, the level of electromagnetic noise, the retransmission rate of data, and success or failure of wireless communication). In the present embodiment, the information collector 21 is a radio wave receiver that can receive radio waves in the wireless communication between the transport vehicles 1 and the wireless communicator 3.

In the present embodiment, each movable object 2 further includes a movable object communicator 22. The movable object communicator 22 is a communication device that performs wireless communication with a communication target O. The communication target O is at least one of the wireless communicator 3 or any of the transport vehicles 1. In the present embodiment, the communication target O is the wireless communicator 3.

As shown in FIG. 3, the transport facility 100 in the present embodiment further includes a transport vehicle controller 6 and a movable object controller 7.

The transport vehicle controller 6 communicates with each of the multiple transport vehicles 1 through the wireless communicator 3 to control the multiple transport vehicles 1. In the present embodiment, the transport vehicle controller 6 is connected to the multiple wireless transmitter-receivers 31 with a communication network N. The communication network N may be wired, wireless, or a combination of both.

In the present embodiment, each transport vehicle 1 includes a controller (not shown) for controlling its operations (e.g., traveling and transfer of the transport article W). The transport vehicle controller 6 communicates with the transport vehicle communicator 13 in each transport vehicle 1 through the wireless communicator 3 to provide commands for the above operations to the controller in the transport vehicle 1.

The movable object controller 7 controls the movable objects 2. The movable object controller 7 may be, for example, incorporated in a tablet terminal or in a controller operable by an operator. In the present embodiment, each movable object 2 includes a controller (not shown) for controlling its operations, such as moving (flying in the present example) and collection of the communication state information i with the information collector 21. The movable object controller 7 performs wireless communication with the movable object communicator 22 in each movable object 2 to provide commands for the above operations to the controller in the movable object 2.

In the present embodiment, each movable object 2 identifies its current position. The movable object controller 7 then obtains, from each movable object 2, position information indicating the current position of the movable object 2. The movable object controller 7 obtains, from each movable object 2, the communication state information i collected with the information collector 21 and stores the communication state information i into a storage (not shown) included in the movable object controller 7 in a manner associated with the above position information.

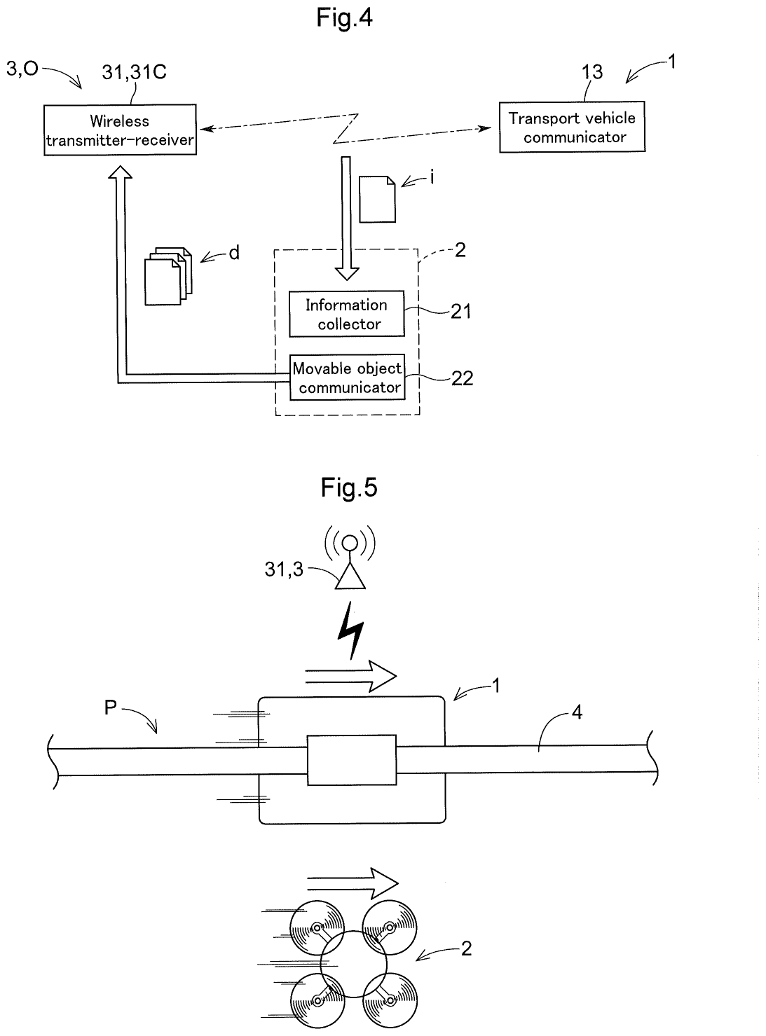

As shown in FIG. 4, the movable object communicator 22 in the present embodiment performs a load applying process. The information collector 21 collects the communication state information i during the load applying process. The load applying process is a process of communicating with the communication target O (the destination transmitter-receiver 31C in the wireless communicator 3 in this example) to increase a communication load on the communication target O. In the present embodiment, the movable object communicator 22 transmits, in the load applying process, a large volume of load data d to the destination transmitter-receiver 31C.

In the load applying process, the communication speed in the wireless communication between the movable object communicator 22 and the destination transmitter-receiver 31C may be preset to a sufficiently high value, and the communication volume of the load data d per unit time may be calculated as a maximum measured value of the communication speed in the wireless communication between the transport vehicle communicator 13 and the destination transmitter-receiver 31C. The movable object communicator 22 in a first movable object 2 of the multiple movable objects 2 may transmit the large volume of load data d to the movable object communicator 22 in a second movable object 2, and the communication volume of the load data d per unit time in the transmission may be calculated as the maximum measured value of the communication speed in the wireless communication between the transport vehicle communicator 13 and the destination transmitter-receiver 31C. In this case, with wireless communication typically performed on a common channel, the communication speed in the wireless communication performed by the movable object communicator 22 can be used as the communication speed in the wireless communication between the transport vehicle communicator 13 and the destination transmitter-receiver 31C.

As shown in FIG. 5, the movable object 2 in the present embodiment collects the communication state information i with the information collector 21 while moving along the rails 4. In the present example, the movable object 2 collects the communication state information i with the information collector 21 while moving in areas adjacent to the transport vehicle 1 for which the communication state information i is collected.

### Other Embodiments

(1) In the above embodiment, each movable object 2 collects the communication state information i with the information collector 21 while moving along the rails 4. In some embodiments, for example, the movable object 2 may move closer to the wireless transmitter-receiver 31 for which the communication state information i is collected and collect the communication state information i with the information collector 21.

(2) In the above embodiment, the movable objects 2 are movable on a path different from the movement path P for the transport vehicles 1. In some embodiments, the movable objects 2 may move on the movement path P for the transport vehicles 1 (or may be, for example, vehicles that travel on the rails 4). Such movable objects 2 may transport, similarly to the transport vehicle 1, transport articles W in normal operations or may be dedicated to collecting the communication state information i without transporting transport articles W.

(3) In the above embodiment, the communication target O is the wireless communicator 3. In some embodiments, the communication target O may be the transport vehicles 1 instead of the wireless communicator 3, or may be both the wireless communicator 3 and the transport vehicles 1.

(4) In the above embodiment, the movable object controller 7 provides commands to the controller in each movable object 2. In some embodiments, for example, the movable object controller 7 may be incorporated in each of the multiple movable objects 2 to allow the corresponding movable object 2 to operate independently of the others or cooperate with the others.

(5) In the above embodiment, the movable object communicator 22 transmits a large volume of load data d to the destination transmitter-receiver 31C in the load applying process. In some embodiments, for example, the movable object communicator 22 may generate electromagnetic noise in the load applying process. In this structure, the information collector 21 in another movable object 2 of the multiple movable objects 2 may collect the communication state information i.

(6) In the above embodiment, the wireless transmitter-receivers 31 are installed at multiple locations along the movement path Pin the transport facility 100. In some embodiments, for example, at least one of the multiple wireless transmitter-receivers 31 may be mounted on one of the movable objects 2. In this structure, when the transport vehicle communicator 13 cannot perform wireless communication with the wireless transmitter-receivers 31 installed at multiple locations along the movement path P due to, for example, a lower radio field intensity, the transport vehicle communicator 13 can perform wireless communication with the wireless transmitter-receiver 31 mounted on the movable object 2.

(7) The structure described in each of the above embodiments may be combined with any other structures described in the other embodiments unless any contradiction arises. For other structures as well, the embodiments described herein are merely illustrative in all aspects. Thus, the embodiments described herein may be modified variously as appropriate without departing from the spirit and scope of the disclosure.

### Overview of Present Embodiment

An overview of the transport facility described above is provided below.

A transport facility includes at least one transport vehicle that transports a transport article along a movement path, a wireless communicator that performs wireless communication with the at least one transport vehicle, and a movable object movable separately from the at least one transport vehicle. The movable object includes an information collector that collects communication state information indicating a state of wireless communication between the at least one transport vehicle and the wireless communicator.

In this structure, the communication state information indicating the state of the wireless communication between the transport vehicle and the wireless communicator can be collected by the movable object moving separately from the transport vehicle. The state of the wireless communication between the transport vehicle and the wireless communicator can thus be monitored easily based on the communication state information. This allows, for example, determination as to whether the wireless communication environment between the transport vehicle and the wireless communicator is appropriate and improves the wireless communication environment.

In this structure, the movable object moves separately from the transport vehicle, and can collect the communication state information without affecting transportation of a transport article performed by the transport vehicle.

The movable object may further include a communication device that performs wireless communication with a communication target. The communication target may be at least one of the wireless communicator or the at least one transport vehicle.

The communication device may perform a load applying process of communicating with the communication target to increase a communication load on the communication target.

The information collector may collect the communication state information during the load applying process.

This structure can collect the communication state information in a severe environment for wireless communication between the transport vehicle and the wireless communicator. The structure can thus more accurately determine whether the wireless communication environment between the transport vehicle and the wireless communicator is appropriate, improving the wireless communication environment more appropriately.

The transport facility may further include a rail extending along the movement path.

The at least one transport vehicle may travel on the rail.

The movable object may be movable on a path different from the movement path, and may collect the communication state information with the information collector while moving along the rail.

In this structure, the movable object can move on a path different from the movement path for the transport vehicle, and can thus collect communication state information efficiently.

Further, in this structure, the movable object collects the communication state information while moving along the rail in the movement path for the transport vehicle, and can thus collect the communication state information indicating a state close to the actual state of the wireless communication between the transport vehicle and the wireless communicator.

The at least one transport vehicle may include a plurality of transport vehicles.

The transport facility may further include a transport vehicle controller that communicates with each of the plurality of transport vehicles through the wireless communicator to control the plurality of transport vehicles.

The wireless communicator may include a plurality of wireless transmitter-receivers arranged in a distributed manner.

Each of the plurality of transport vehicles may be connected to and communicate with a destination transmitter-receiver selected from the plurality of wireless transmitter-receivers, and move along the movement path while switching the destination transmitter-receiver.

In this structure, the plurality of wireless transmitter-receivers are arranged in a distributed manner. Each of the plurality of transport vehicles is then, while moving along the movement path, connected to the destination transmitter-receiver selected from the plurality of wireless transmitter-receivers to perform wireless communication with the destination transmitter-receiver. Thus, the state of the wireless communication easily varies based on both the location and time. The structure can appropriately monitor, with the movable object collecting the communication state information as described above, the state of the wireless communication that can vary easily based on the location and time.

### INDUSTRIAL APPLICABILITY

The technique according to one or more embodiments of the disclosure is applicable to a transport facility including a transport vehicle that transports a transport article and a wireless communicator that performs wireless communication with the transport vehicle.

What is claimed is:

1. A transport facility, comprising:
at least one transport vehicle configured to transport a transport article along a movement path;
a wireless communicator configured to perform wireless communication with the at least one transport vehicle; and
a movable object movable separately from the at least one transport vehicle, and
wherein the movable object comprises an information collector configured to collect communication state information indicating a state of wireless communication between the at least one transport vehicle and the wireless communicator.

2. The transport facility according to claim 1, wherein:
the movable object further comprises a communication device configured to perform wireless communication with a communication target, and the communication target is at least one of the wireless communicator or the at least one transport vehicle,
the communication device performs a load applying process of communicating with the communication target to increase a communication load on the communication target, and
the information collector collects the communication state information during the load applying process.

3. The transport facility according to claim 1, further comprising:
a rail extending along the movement path,
wherein the at least one transport vehicle travels on the rail, and
wherein the movable object is movable on a path different from the movement path, and collects the communication state information with the information collector while moving along the rail.

4. The transport facility according to claim 1, wherein:
the at least one transport vehicle comprises a plurality of transport vehicles,
the transport facility further comprises a transport vehicle controller configured to communicate with each of the plurality of transport vehicles through the wireless communicator to control the plurality of transport vehicles,
the wireless communicator comprises a plurality of wireless transmitter-receivers arranged in a distributed manner, and
each of the plurality of transport vehicles is connected to and communicates with a destination transmitter-receiver selected from the plurality of wireless transmitter-receivers, and moves along the movement path while switching the destination transmitter-receiver.
